(19) United States
(12) Patent Application Publication
(10) Pub. No.: US 2026/0081608 A1
(43) Pub. Date: Mar. 19, 2026

(54) CLOCK GENERATOR USING MULTIPLYING DELAY-LOCKED LOOP WITH CURRENT REPLICA CELL

(71) Applicant: SEOUL NATIONAL UNIVERSITY R&DB FOUNDATION, Seoul (KR)

(72) Inventors: Woo Seok CHOI, Seoul (KR); Ha Jung PARK, Seoul (KR)

(21) Appl. No.: 19/298,586

(22) Filed: Aug. 13, 2025

(30) Foreign Application Priority Data
Sep. 13, 2024 (KR) 10-2024-0125430

(51) Int. Cl. H03L 7/099; H03L 7/093

(52) U.S. Cl. CPC H03L 7/099; H03L 7/093

(57) ABSTRACT

An oscillator configured in a multiplying delay locked loop according to an embodiment includes: a signal input unit configured to apply a reference clock at predetermined intervals; an inverter unit connected to the signal input unit and configured to oscillate and generate an output clock based on a level of a drain voltage dropped from a power supply voltage according to a current supplied by the reference clock; and a current supply unit configured to supply a predetermined current through a node of the drain voltage before the predetermined interval returns after the inverter unit operates, wherein the inverter unit includes a CMOS inverter connected between the drain voltage and ground.

### CROSS-REFERENCE TO RELATED APPLICATION

This application is based on and claims priority under 35 U.S.C. §119 to Korean Patent Application No. 10-2024-0125430, filed on Sep 13th, 2024, in the Korean Intellectual Property Office, the disclosure of which is incorporated by reference herein in its entirety.

### BACKGROUND

### 1. Field

The present disclosure relates to the field of clock generators, and more particularly, to an oscillator having a structure for supplying current by itself, and a multiplying delay-locked loop including the same.

### 2. Description of the Related Art

The present disclosure relates to clock synchronization circuits that minimize the phase difference between data and clock signals in modern memory systems and communication interfaces, with a Delay-Locked Loop (DLL) being a representative example.

A DLL detects a phase difference by feeding back a signal whose phase has been delayed from the output clock and comparing it with a reference clock, and synchronizes the output clock phase by adjusting the delay time accordingly.

Compared to Phase-Locked Loops (PLLs), DLLs are less susceptible to noise and produce less jitter, while also being faster. However, as they synchronize only the phase of a signal without changing the frequency, they are mainly used in low- and mid-frequency applications where phase accuracy and stability are critical.

In response, a Multiplying Delay-Locked Loop (MDLL), which extends the concept of DLLs, has emerged. MDLLs are increasingly recognized as more suitable synchronization circuits for recent technological trends such as high-speed data communication and high-frequency signal processing through frequency multiplication.

Recently, with the growing ubiquity of high-speed interfaces, power consumption of circuits has become a critical issue. To reduce power usage during idle states, conventional methods have involved disabling the supply voltage to certain circuits.

For example, when communication is halted, circuits not required for operation are deactivated. However, when the clock generator is reactivated, it takes some time for it to stabilize to the desired frequency, which can lead to increased overall latency in the system.

More specifically, when the power of the DLL or MDLL is off, no current flows through the oscillator, and the drain voltage of the PMOS transistors in the inverter circuits of the oscillator equals the supply voltage (VDD). After the reference clock is applied and the circuit begins to operate, the drain voltage drops below VDD, but since the oscillator halts until the next reference clock arrives, the drain voltage rises again. As a result, the oscillator operates at a faster frequency than desired, which can increase the loop's lock time.

Accordingly, there is a need for a method to quickly stabilize the output frequency of a clock signal and achieve phase locking when initiating operation from an inactive loop state.

### 3. Prior Art Document

Republic of Korea Unexamined Patent Publication No. 10-0807116 (Title: Delay Locked Loop)

### SUMMARY

The present disclosure aims to address the problems of the prior art by providing a clock generator based on a multiplying delay-locked loop (MDLL) that induces frequency stabilization by autonomously supplying current while waiting for the reference clock.

It should be noted, however, that the technical objectives of the present embodiment are not limited to those described above, and other objectives may also be achieved.

According to one embodiment of the present disclosure, a multiplying delay-locked loop (MDLL) comprises: a phase detector configured to detect a phase difference between a reference clock and an input signal; a loop filter configured to output a control word for synchronizing the reference clock and the input signal based on the phase difference; and an oscillator configured to generate a frequency in response to the control word and to output a feedback output clock to the phase detector.

In one embodiment of the present disclosure, the oscillator includes: a signal input unit configured to apply the reference clock at predetermined intervals; an inverter unit connected to the signal input unit and configured to generate an output clock through oscillation based on a drain voltage drop from a supply voltage caused by a current supplied by the reference clock; and a current supply unit configured to supply a predetermined current to a drain voltage node after the operation of the inverter unit but before the next interval of the reference clock arrives, wherein the inverter unit includes a CMOS inverter connected between the drain voltage and ground.

According to one embodiment of the present disclosure, the degree to which the drain voltage increases during the interval of the reference clock can be suppressed depending on the current level supplied by the current supply unit.

In another embodiment of the present disclosure, a method of operating the oscillator includes: applying a reference clock at predetermined intervals; generating an output clock through oscillation based on the level of drain voltage drop from a supply voltage caused by current supplied via the reference clock; and supplying a predetermined current to the drain voltage node after the output clock is generated but before the next interval of the reference clock.

The technical means for solving the problems described above in the present disclosure provide a clock generator capable of high-speed synchronization and rapid circuit stabilization by eliminating the issue of increased output frequency prior to the application of the reference clock. As a result, it enables fast switching between power modes for circuit reactivation while reducing power consumption in high-speed interfaces.

The clock generator according to one embodiment of the present disclosure can be applied to a wide range of fields, including wired/wireless communications and memory systems, which require low power.

The advantages of the present disclosure are not limited to those mentioned above, and other effects not explicitly stated will be clearly understood by those skilled in the art from the following description.

### BRIEF DESCRIPTION OF THE DRAWINGS

FIG. 1 is a block diagram of a multiplying delay-locked loop according to an embodiment of the present disclosure.

FIG. 2 is a circuit diagram of an oscillator according to an embodiment of the present disclosure.

FIG. 3A and FIG. 3B are a circuit diagram of the inverter unit and the current replica cell according to an embodiment of the present disclosure.

FIG. 4, FIG. 5A and FIG. 5B are diagrams supporting the effects provided by an embodiment of the present disclosure.

FIG. 6 is a flowchart illustrating the operation of the multiplying delay-locked loop according to an embodiment of the present disclosure.

FIG. 7 is a flowchart illustrating the operation of the oscillator according to an embodiment of the present disclosure.

### DETAILED DESCRIPTION

The following provides a detailed description of embodiments of the present disclosure with reference to the accompanying drawings, to enable those skilled in the art to readily implement the invention. However, the present disclosure may be implemented in various different forms and is not limited to the embodiments described herein. Parts unrelated to the description are omitted from the drawings for clarity, and like reference numerals are used to refer to like elements throughout the specification.

Throughout the specification, when a component is described as being “connected” to another component, it should be understood to include both “directly connected” and “electrically connected” with one or more intervening components. Furthermore, when a component is described as “including” another component, unless explicitly stated otherwise, it does not exclude the presence of other components and may further include additional components.

As used in this specification, the term “unit” may refer to a hardware-based unit, a software-based unit, or a combination of both. One unit may be implemented using multiple pieces of hardware, or multiple units may be implemented on a single piece of hardware. The term “~unit” is not limited to either software or hardware; it may be configured on an addressable storage medium, or implemented to activate one or more processors. For example, a “~unit” may include software components, object-oriented software components, class components, and task components, as well as processes, functions, attributes, procedures, subroutines, program code segments, drivers, firmware, microcode, circuits, data, databases, data structures, tables, arrays, and variables. The functions provided within such components or “~units” may be integrated into fewer components or “~units” or further divided into additional ones. Furthermore, these components or “~units” may be implemented to execute on one or more CPUs within a device.

The following provides a detailed description of embodiments of the present disclosure with reference to the accompanying drawings.

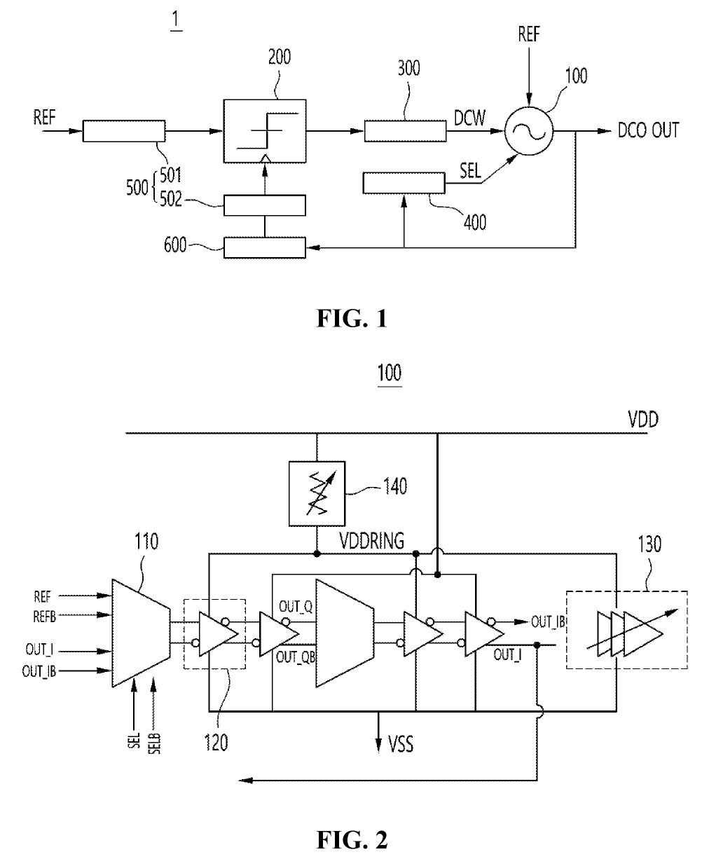

FIG. 1 is a block diagram of a multiplying delay-locked loop according to an embodiment of the present invention. For convenience of explanation, the multiplying delay-locked loop (1) will be referred to as "loop (1)".

Loop (1) is an electronic circuit that performs clock generation and timing control. It may be used for precise control of clock signals in high-speed interfaces and operates by periodically synchronizing the oscillator's output with a reference clock. Compared to a conventional PLL, the loop (1) offers advantages such as lower jitter and lower power consumption.

According to an embodiment, loop (1) operates based on a reference clock input at a fixed period from the outside. The reference clock provides the frequency and phase baseline for the output clock generated by the loop (1). The output clock generated by loop (1) periodically locks its phase to that of the reference clock and may be amplified by an integer multiple or converted to a specific frequency. For example, if the reference clock is 100 MHz, loop (1) may generate high-frequency output clocks such as 200 MHz or 400 MHz.

Referring to FIG. 1, loop (1) includes an oscillator (100), a phase comparator (200), and a loop filter (300). Overall, loop (1) has a structure in which the output of the phase comparator (200) is provided to the input of the loop filter (300), and the oscillator (100) oscillates in response to the control signal generated by the loop filter (300). Furthermore, loop (1) is designed as a feedback loop structure in which the output clock (DCO OUT) of the oscillator (100) is fed back and periodically input to the phase comparator (200) along with the reference clock (REF).

The phase comparator (200) functions as a sampler, comparing the phase of the reference clock (REF) with that of the input signal and detecting the phase difference. Here, the input signal refers to the output clock (DCO OUT) that is generated by the oscillator (100) and periodically fed back. The phase difference represents how much one signal leads or lags the other with the same period, and the phase comparator (200) can convert the detected phase difference into a digital signal or voltage and provide it to the loop filter (300).

In one embodiment, the phase comparator (200) may detect the phase difference by comparing the edges (transitions) of the reference clock (REF) and the input signal (DCO OUT). The phase comparator (200) generates a signal reflecting the phase difference and provides it to the loop filter (300) in the form of a digital pulse or code. This signal provided to the loop filter (300) can be used as a basis for adjusting the frequency or phase of the output clock (DCO OUT).

As an additional embodiment, the phase comparator (200) may be configured using D flip-flops and logic gates. For example, the phase comparator (200) may include a first D flip-flop that uses the reference clock (REF) as a clock input and the output clock (DCO OUT) as a data (D) input, and a second D flip-flop that receives the opposite input of the first. Additionally, the phase comparator (200) may include logic gates that receive the outputs of the first and second D flip-flops and process them using AND, OR, XOR, or combinations thereof to generate a signal corresponding to the phase difference. Through this structure, the phase comparator (200) can detect the phase difference between the reference clock (REF) and the output clock (DCO OUT) based on rising or falling edges. That is, the outputs of the first and second D flip-flops can represent the relative phase positions of each signal, and the phase comparator (200) can pass these outputs through logic gates to generate a signal corresponding to the final phase difference.

The phase comparator (200) of this embodiment, which is based on D flip-flops, has the advantages of strong noise resistance and ease of implementation in integrated circuits. However, it is not limited to this configuration and may also be implemented using other methods such as charge pump-based, XOR-based, or triangular wave-based approaches.

The loop filter (300) outputs a control word (DCW) to synchronize the reference clock (REF) and the output clock (DCO OUT) based on the phase difference received from the phase comparator (200). Specifically, the loop filter (300) may receive a digital signal representing the phase difference, which is recognized as a phase error, from the phase comparator (200). The loop filter (300) may perform filtering to remove high-frequency noise from the received signal. Based on the filtered signal, the loop filter (300) may generate a digital control word (DCW) to control the oscillator (100). This control word (DCW) can be used to finely adjust the oscillation frequency of the oscillator (100) to align the phase of the output clock (DCO OUT) with that of the reference clock (REF).

The oscillator (100) generates a frequency based on the control word (DCW) output from the loop filter (300), outputs the resulting output clock (DCO OUT), and feeds it back to the phase comparator (200). In addition, a reference clock (REF) is applied to the oscillator (100) at predetermined intervals, and the oscillator (100) operates based on this input to generate the output clock (DCO OUT) with a fixed-frequency waveform. That is, the oscillator (100) is reset at each period when the reference clock (REF) is applied, and the reference clock (REF) functions as a signal to synchronize the oscillator (100). A more detailed embodiment of the oscillator (100) will be described later.

In one embodiment, the loop (1) may further include a logic circuit (400) that controls the application of the reference clock (REF) to the oscillator (100) at each set period. That is, in response to the output clock (DCO OUT) generated by the oscillator (100), the logic circuit (400) outputs a selection signal (SEL) at each period according to a predetermined digital logic, and this signal may be provided to the oscillator (100) to function as a command for applying the reference clock (REF).

In one embodiment, the loop (1) may further include at least one delay circuit (Digitally Controlled Delay Line; DCDL, 500). For example, the delay circuit (500) may include a first delay circuit (501) that receives the reference clock (REF) periodically provided from the outside and adjusts the arrival time to the phase comparator (200) by adding a variable delay. In addition, the delay circuit (500) may include a second delay circuit (502) that receives the output clock (DCO OUT) generated by the oscillator (100) and fed back as an input signal and adjusts its arrival time to the phase comparator (200) by adding a variable delay. In other words, the first delay circuit (501) and the second delay circuit (502) adjust the delay times of the reference clock (REF) and the output clock (DCO OUT), respectively, and perform the role of synchronizing the input times of both clocks to the phase comparator (200).

In one embodiment, the oscillator (100) may generate a high-frequency signal relative to the reference clock (REF). That is, the output clock (DCO OUT) is synchronized with the reference clock (REF), but can be generated as a high-frequency signal through amplification or conversion, and in this context, the loop (1) may further include a frequency divider (Driver, 600). The frequency divider (600) is connected to the oscillator (100), divides the output clock (DCO OUT) by a predetermined division ratio, and feeds it back to the phase comparator (200). That is, the frequency divider (600) divides the high-frequency output clock (DCO OUT) at a certain ratio so that it matches the frequency of the reference clock (REF), outputs it as a low-frequency feedback signal, and delivers it to the phase comparator (200). The delivered feedback signal serves as the input signal to the phase comparator (200) and is compared to the phase of the reference clock (REF). Meanwhile, when the loop (1) includes the frequency divider (600), the logic circuit (400) may output a selection signal (SEL) that controls the application of the reference clock (REF) in response to the output of the oscillator (100) or the frequency divider (600).

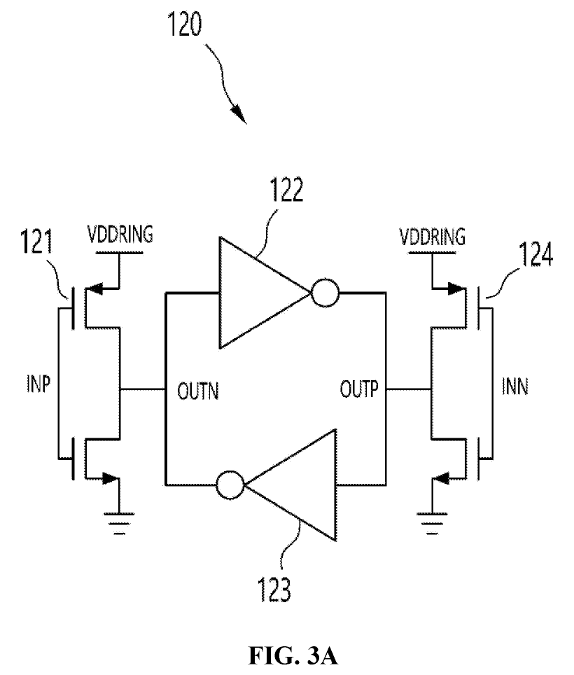

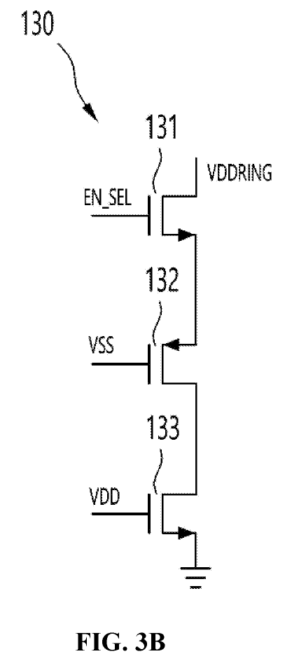

The following describes the oscillator (100) included in the loop (1) in more detail with reference to FIGS. 23A and 3B. FIG. 2 is a circuit diagram of the oscillator according to an embodiment of the present invention.

Referring to FIG. 2, the oscillator (100) includes a signal input unit (110) and an inverter unit (120) connected in series. The signal input unit (110) is configured to apply the reference signal (REF) to the inverter unit (120) at each predetermined period, and the inverter unit (120) is composed of a plurality of inverters connected in series that oscillate based on the reference signal (REF). Additionally, at least one inverter unit (120) may be connected in series. The oscillator (100) is fundamentally designed such that the output clock (OUT_I) ultimately generated by the oscillation of the final inverter in the previous cycle is fed back to the signal input unit (110).

Meanwhile, as shown in FIG. 2, it is preferable for the signals input to and output from the oscillator (100) to be composed of differential signals for improved stability. For example, OUT_I represents the positive signal of the output clock, and OUT_IB represents the negative signal. The other signal labels shown follow the same concept.

In one embodiment, the signal input unit (110) may be implemented as a multiplexer that selectively outputs either the reference clock (REF) or the output clock (OUT) fed back by the inverter unit (120). That is, the signal input unit (110) may be configured to apply the reference clock (REF) to the inverter unit (120) at each cycle, and to apply the output clock (OUT) from the previous cycle otherwise. At this time, the signal input unit (110) may output the reference clock (REF) under the control of a selection signal (SEL) input each cycle through the loop (1), and as described above, the selection signal (SEL) may be output via the logic circuit (400). The oscillator (100) generates a predetermined frequency according to the level of the drain voltage (VDDRING), and can continuously generate the output clock (OUT) in response to the reference clock (REF) through the multiplexer.

In one embodiment, the inverter unit (120) may include CMOS inverters connected between the drain voltage (VDDRING) and ground (VSS). In other words, the inverter unit (120) has its frequency determined by the drain voltage (VDDRING) of the PMOS with VDD as the supply voltage and may be designed such that the source terminal of the NMOS is connected to ground (VSS).

The circuit diagram of the inverter unit (120) according to an embodiment of the present invention is illustrated in FIG. 3A. Referring to FIG. 3A, the inverter unit (120) includes a first inverter (121), a second inverter (122) and a third inverter (123) connected in a feedback configuration and connected to the output terminal of the first inverter (121), and a fourth inverter (124) connected to the output terminal of the second inverter (122). More specifically, the input terminal of the second inverter (122) and the output terminal of the third inverter (123) are connected to the output terminal of the first inverter (121), and the input terminal of the fourth inverter (124) is connected to the node where the output terminal of the second inverter (122) and the input terminal of the third inverter (123) meet. The first through fourth inverters (121, 122, 123, 124) may be implemented as CMOS inverters in which PMOS and NMOS are connected in series. In addition, the PMOS of the first and fourth inverters (121, 124) has its drain connected to VDDRING, the NMOS source is connected to ground, and input signals (INP, INN) are applied to the gates of the PMOS and NMOS, respectively. Furthermore, the second and third inverters (122, 123) may function as memory elements for storing predetermined data.

The inverter unit (120), using logic gates, inverts the input signal and outputs OUTP and OUTN in a crossed differential fashion. That is, INP and INN are differential input signals, such that when INP is HIGH, INN is LOW. These input signals are applied to the gates of the PMOS and NMOS, respectively, resulting in the opposing inverter outputting the OUTP and OUTN signals. OUTP and OUTN also maintain opposite states. The inverter unit (120) is designed with this differential inverter structure to enable stable clock signal handling and high-speed operation.

In one embodiment, referring to FIG. 2, the oscillator (100) may further include a voltage drop element (140) connected between the supply voltage (VDD) node and the drain voltage (VDDRING) node. The voltage drop element (140) is a load controllable via predetermined digital logic and, when the oscillator (100) begins operation in response to the application of the reference signal (REF), serves to reduce the drain voltage (VDDRING) from the VDD level.

In one embodiment, to extract and match multiple phases, multiple sets of the signal input unit (110) and inverter unit (120) may be configured and connected in series. For example, a second multiplexer and inverter chain shown in FIG. 2 may be configured to finely adjust the clock signal via frequency tuning, phase compensation, or delay. Specifically, the first multiplexer and inverter chain may perform initial signal processing and phase alignment to output an auxiliary output clock (OUT_Q) of the first phase. Based on this, the second multiplexer and inverter chain may fine-tune the first phase to determine the final output clock (OUT_I) of the matched second phase. In this manner, the present embodiment enables the loop (1) to generate multi-phase clocks, facilitating precise phase locking.

Based on the foregoing embodiment, the operation of the oscillator (100) by the signal input unit (110) and the inverter unit (120) proceeds as follows. First, when the power of the loop (1) is turned off (OFF), no current flows through the oscillator (100), and the level of the drain voltage (VDDRING) of the inverter unit (120) remains the same as the supply voltage (VDD). Subsequently, when the power is turned on (ON) and the designated cycle arrives, the signal input unit (110) selectively outputs the reference clock (REF) under the control of the selection signal (SEL). When the voltage of the reference clock (REF) is applied to the inverter unit (120), the oscillator (100) begins operating based on the current supplied from the reference clock, and the drain voltage (VDDRING) drops from the supply voltage (VDD) level due to the voltage drop element (140). Consequently, the inverter unit (120) oscillates at a frequency determined by the level of the drain voltage (VDDRING) and generates the output clock (OUT_I), which is fed back to the signal input unit (110) and the phase comparator (200). This process is periodically repeated to achieve phase locking of the output clock (OUT_I) via the loop (1).

However, during the interval between adjacent cycles in the above operation, an idle period may occur during which the oscillator (100) remains inactive. That is, after the inverter unit (120) operates, the circuit is inactive until the next reference clock (REF) is applied, causing the drain voltage (VDDRING) to rise again toward the supply voltage (VDD). As a result, the oscillator (100) may operate faster than the originally set frequency, which can increase the phase lock time of the loop (1).

To address this issue, the oscillator (100) of the present invention includes a current supply unit (130) that autonomously provides current to the circuit. The current supply unit (130) is a circuit designed to replicate current or stabilize voltage, and may be defined as a "current replica cell."

Referring to FIG. 2, the current supply unit (130) may be formed with at least one or more cells connected and operates to supply a predetermined current along the node of the drain voltage (VDDRING) connected to the inverter unit (120). That is, the current supply unit (130) can serve to suppress the rise of the drain voltage (VDDRING) before the next reference signal (REF) is applied after the output clock (OUT_I) has been generated.

In one embodiment, the oscillator (100) may suppress the degree to which the drain voltage (VDDRING) rises during the return of the preset cycle depending on the level of current supplied by the current supply unit (130). Specifically, the supply current of the current supply unit (130) can be set to maintain the level of the drain voltage (VDDRING) until the next reference clock (REF) is applied, thereby continuously outputting a waveform at the designated frequency.

FIG. 3B shows a circuit diagram of the current supply unit (130) according to an embodiment of the present invention. The current supply unit (130) may be designed to be controlled by a predetermined digital logic within the oscillator (100). For example, the current supply unit (130) may include a first switching element (131) having the drain voltage (VDDRING) applied to one terminal and a drive signal (EN_SEL) applied to its gate; a second switching element (132) having one terminal connected in series to the other terminal of the first switching element (131); and a third switching element (133) having one terminal connected in series to the other terminal of the second switching element (132) and the other terminal grounded. More specifically, the first switching element (131) may be formed of an NMOS, the second switching element (132) of a PMOS, and the third switching element (133) of an NMOS. The second switching element (132) has its gate connected to ground (VSS), and the third switching element (133) is always activated by being applied with the supply voltage (VDD). Accordingly, when the drive signal (EN_SEL) is applied, the first switching element (131) turns on, forming a current path.

In one embodiment, the current supply unit (130) may be designed to operate and turn off for a predetermined time based on digital logic. That is, the current supply unit (130) can be controlled to operate only during specific cycles, thereby preventing the supply current from overlapping or colliding with the reference clock (REF) and minimizing power consumption.

In another embodiment, if the loop (1) includes a logic circuit (400), the current supply unit (130) may operate in response to the selection signal (SEL) output by the logic circuit (400). In this case, the current supply unit (130) may be designed to supply current before the reference clock (REF) is delivered to the inverter unit (120).

In one embodiment, the current supply unit (130) may be designed such that the supply current level is adjustable by digital logic. For example, a thermometer code consisting of 0s and 1s, matched with the current supply level, may be preset. Based on the level change of the drain voltage (VDDRING), the current supply unit (130) may adjust the supply current level according to the determined thermometer code.

In yet another embodiment, referring to FIG. 3B, it is desirable that the current supply unit (130) be formed with a transistor structure corresponding to the inverters of the inverter unit (120), matched to the current mirroring ratio of the oscillator (100). Based on this structure, when EN_SEL is applied in response to the rise of VDDRING before the reference clock (REF) is applied according to the SEL signal, a fixed voltage is applied to the gate, turning on the PMOS and allowing current to be supplied to the VDDRING node.

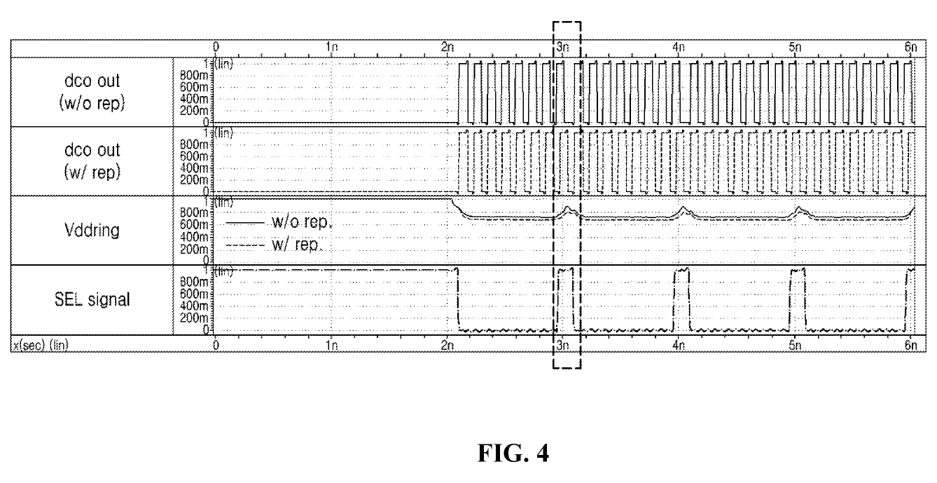

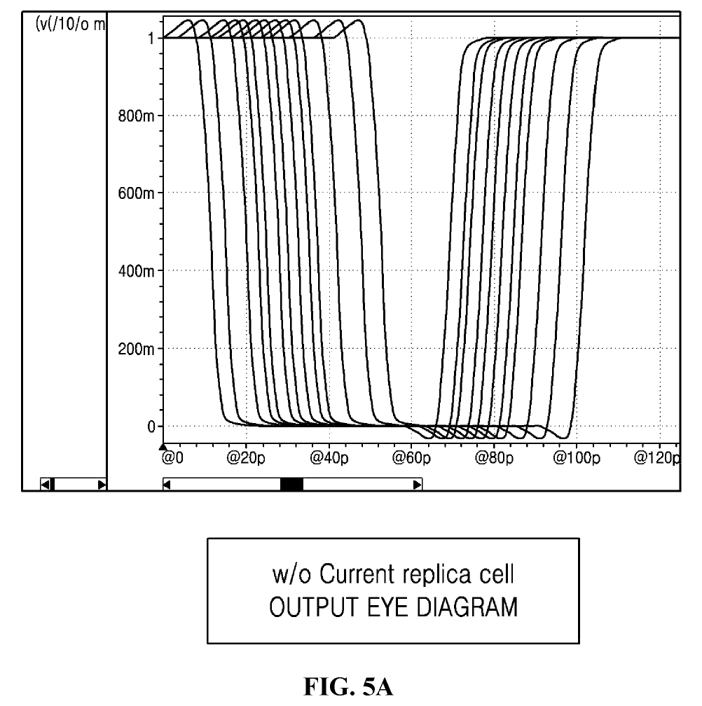

The effects of the present invention according to the features of the current supply unit (130) are explained below. FIGS. 4 and 5 are diagrams supporting the effects provided by an embodiment of the present invention.

FIG. 4 is a graph comparing the output clock (DCO OUT) depending on whether the current supply unit (130) is configured. Here, "rep" denotes the current supply unit (130), and the waveform of the SEL signal indicates the application period of the reference clock (REF). Focusing on the dashed box area in the graph, it can be observed that in the graph without the current supply unit (w/o rep), the drain voltage (Vddring) rises before the reference clock (REF) is applied, resulting in an unstable state where the output frequency increases. In contrast, in the graph with the current supply unit (w/rep), the rise in Vddring is suppressed, and the output frequency remains relatively stable. In particular, referring to the graph, considering that the operating range of Vddring lies between 600–800 mV, the Vddring rises approximately 50 mV less when the current supply unit (130) is present. Thus, the experimental data in FIG. 4 supports that the current supply unit (130) significantly contributes to frequency stability.

FIG. 5A and 5B compare the output waveform of the oscillator (100) depending on whether the current supply unit (130) is present. FIG. 5A shows the eye diagram of the output waveform when the current supply unit (130) is not configured, and FIG. 5B shows the eye diagram of the output waveform when the current supply unit (130) is configured according to the present invention. Comparing both graphs confirms that the jitter of the signal output by the oscillator (100) is significantly improved by the current supply unit (130).

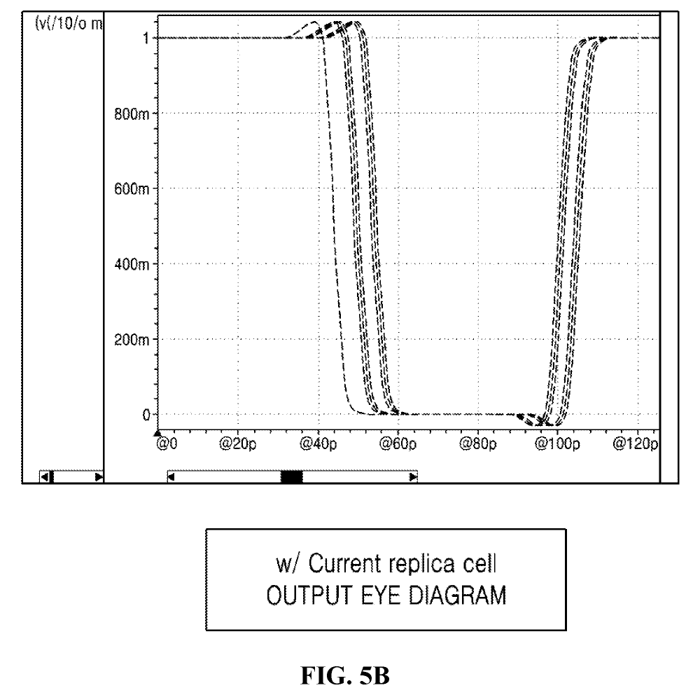

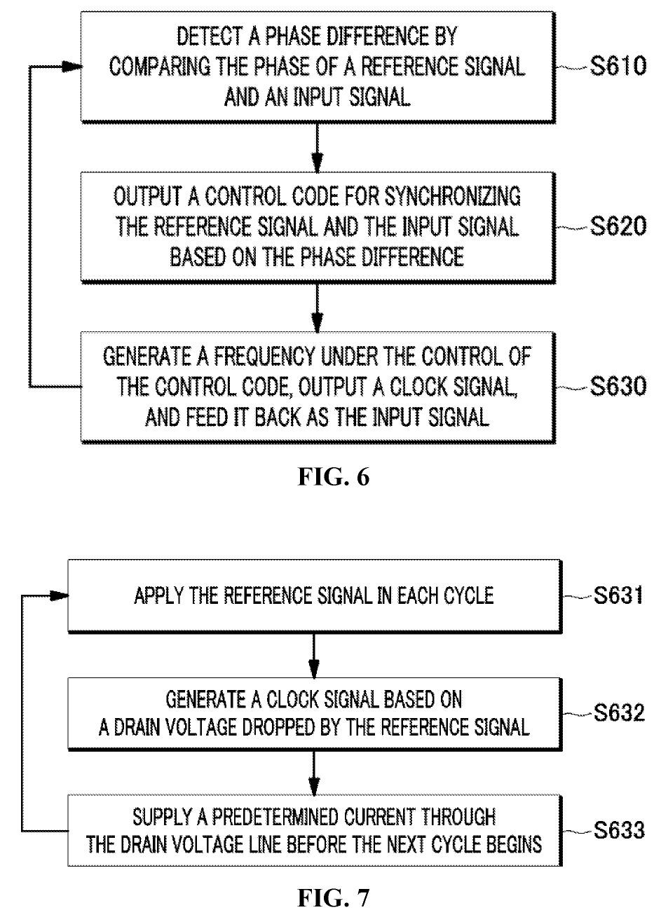

Hereinafter, with reference to FIG. 6, an embodiment of the operating method of the loop (1) will be described. FIG. 6 is a flowchart of the operation of the multiplying delay-locked loop according to an embodiment of the present invention. Some overlapping content will be omitted.

In S610, the phase comparator (200) compares the phase of the reference clock and the input signal (output clock) fed back from the oscillator (100) to detect the phase difference.

In an embodiment, the reference clock and output clock may be input to the phase comparator (200) in a synchronized manner via the first and second delay lines, respectively.

In S620, the loop filter (300) receives the phase difference signal from the phase comparator (200) and outputs a control word to synchronize the reference clock and the output clock.

In S630, the oscillator (100) generates a frequency under the control of the control word output from the loop filter (300) to regenerate the output clock. The generated output clock is fed back to the phase comparator (200), and S610 is repeated.

In one embodiment, the output clock generated in S630 may be input to the frequency divider (600), divided into a low-frequency signal corresponding to the reference clock, and then provided to the phase comparator (200).

In another embodiment, the oscillator (100) may oscillate based on the reference clock input at each preset cycle and generate an output clock of a predetermined frequency. In this case, in response to the output clock generated in the previous cycle, the logic circuit (400) configured in the loop outputs a selection signal, which is applied to the oscillator as a control signal for applying the reference clock.

Hereinafter, an embodiment of the operation method of the oscillator (100) performed in S630 will be described in more detail. FIG. 7 is a flowchart of the operation of the oscillator (100) according to an embodiment of the present invention. Some overlapping content will be omitted as previously described.

In S631, when a preset cycle is reached, the oscillator (100) applies the reference clock internally. For example, the multiplexer (mux) configured in the oscillator (100) selectively outputs the reference clock according to the selection signal delivered by the logic circuit (400). When the voltage of the reference clock is applied, the oscillator (100) is activated.

In S632, the oscillator (100) oscillates based on the current supplied by the reference clock and generates the output clock according to the level of the drain voltage dropped from the power supply voltage. The output clock thus generated may be input back to the multiplexer as feedback.

In S633, after the output clock is generated, the oscillator (100) supplies a predetermined current through the drain voltage node before the next preset cycle arrives.

In one embodiment, the extent to which the drain voltage rises during the returning preset cycle may be reduced according to the level of current supplied through the drain voltage node.

In another embodiment, the oscillator (100) may control the supply of a predetermined current through a predetermined digital logic.

In yet another embodiment, the oscillator (100) may supply the predetermined current to the drain voltage node for a preset duration using the digital logic and then stop the supply.

In another embodiment, the oscillator (100) may adjust the level of current supplied to the drain voltage node according to a predetermined thermometer code.

In one example, the oscillator (100) may supply a predetermined current to the drain voltage node, based on a selection signal input through the loop in response to the output clock generated from the reference clock applied in the previous cycle, before the reference clock is applied internally again.

The embodiments of the present invention may also be implemented in the form of a non-transitory recording medium containing computer-executable instructions, such as a program module executed by a computer. A computer-readable medium may be any available medium that can be accessed by a computer and includes both volatile and non-volatile media, as well as removable and non-removable media. The computer-readable medium may include computer storage media. Computer storage media include volatile and non-volatile, removable and non-removable media implemented in any method or technology for storage of information such as computer-readable instructions, data structures, program modules, or other data.

Although the methods and systems of the present invention have been described with reference to specific embodiments, all or part of their components or operations may be implemented using a computer system with a general-purpose hardware architecture.

The above description of the invention is for illustrative purposes only, and those skilled in the art to which the invention pertains will understand that the invention can be easily modified into other specific forms without changing the technical spirit or essential features of the invention. Therefore, the embodiments described above should be understood to be illustrative in all respects and not restrictive. For example, each component described as a single module may be implemented in a distributed manner, and components described as distributed may be implemented in a combined form.

The scope of the present invention should be determined not by the foregoing detailed description but by the claims to be described below, and all modifications or alterations derived from the meanings, ranges, and equivalents of the claims are to be interpreted as falling within the scope of the invention.

### DESCRIPTION OF SYMBOLS

1: Multiplying Delay-Locked Loop

100: Oscillator

200: Phase Comparator

300: Loop Filter

400: Logic Circuit

500: Delay Circuit (DCDL)

501: First Delay Circuit

502: Second Delay Circuit

600: Divider

110: Signal Input Unit

120: Inverter Unit

130: Current Supply Unit

140: Voltage Drop Element

What is claimed is:

1. An oscillator configured in a Multiplying Delay Locked Loop (MDLL),
a signal input unit configured to apply a reference clock at a predetermined interval;
an inverter unit connected to the signal input unit and configured to generate an output clock by oscillating according to a drain voltage level dropped from a power supply voltage based on a current supplied by the reference clock; and
a current supply unit configured to supply a predetermined current through a node of the drain voltage before the predetermined interval returns after the inverter unit operates,
wherein the inverter unit includes a CMOS inverter connected between the drain voltage and ground.

2. The oscillator of claim 1,
wherein a degree to which the drain voltage rises during the predetermined interval is reduced according to a level of the current supplied by the current supply unit.

3. The oscillator of claim 1,
wherein the current supply unit is designed to operate and shut off for a predetermined time under control of a predetermined digital logic, and a level of the supplied current is adjustable according to a predetermined thermometer code.

4. The oscillator of claim 1,
wherein the current supply unit comprises:
a first switching element having one terminal to which the drain voltage is applied and a gate to which a driving signal is applied;
a second switching element having one terminal serially connected to the other terminal of the first switching element; and
a third switching element having one terminal serially connected to the other terminal of the second switching element and the other terminal connected to ground,
wherein the gate of the second switching element is applied with ground, and the gate of the third switching element is applied with the power supply voltage, such that when the driving signal is applied, the first switching element is turned on to form a supply path for the predetermined current.

5. The oscillator of claim 1,
wherein the inverter unit comprises:
a first inverter;
a second inverter having an input terminal connected to an output terminal of the first inverter;
a third inverter having an output terminal connected to the output terminal of the first inverter to form a feedback loop with the second inverter; and
a fourth inverter connected to a node where the output terminal of the second inverter and the input terminal of the third inverter are connected,
wherein the first to fourth inverters are CMOS inverters,
and the first and fourth inverters are configured such that the drain of a PMOS is connected to the drain voltage, the source of an NMOS is connected to ground, and differential signals are applied to the gates of the PMOS and NMOS.

6. The oscillator of claim 1,
wherein the signal input unit comprises a multiplexer that selectively outputs the output clock fed back by the inverter unit and the reference clock,
and outputs the reference clock according to a selection signal input through the loop in response to the feedback output clock,
wherein the current supply unit supplies the predetermined current before the reference clock is output according to the selection signal.

7. A method of operating an oscillator configured in a multiplying delay locked loop,
the method comprising:
applying a reference clock at a predetermined interval;
generating an output clock by oscillating based on a drain voltage level dropped from a power supply voltage according to a current supplied by the reference clock;
and supplying a predetermined current through a node of the drain voltage before the predetermined interval returns after the output clock is generated,
wherein the step of generating the output clock is performed by a CMOS inverter connected between the drain voltage and ground.

8. The method of claim 7,
wherein the supplying step includes attenuating a degree of rise in the drain voltage during the return of the predetermined interval, according to a level of the predetermined current.

9. The method of claim 7,
wherein the supplying step includes supplying the predetermined current for a predetermined time through a predetermined digital logic and then stopping the supply,
and adjusting the current supply level according to a predetermined thermometer code.

10. The method of claim 7,
wherein the supplying step includes supplying the predetermined current,
based on a selection signal input through the loop in response to an output clock generated based on a reference clock applied in a previous cycle, before the reference clock is reapplied.

11. A multiplying delay locked loop, comprising:
a phase detector configured to detect a phase difference between a reference clock and an input signal;
a loop filter configured to output a control word for synchronizing the reference clock and the input signal based on the phase difference; and
an oscillator configured to generate a frequency based on the control word and output an output clock that is fed back as an input signal to the phase detector,
wherein the oscillator comprises:
a signal input unit configured to apply the reference clock to the loop at a predetermined interval;
an inverter unit connected to the signal input unit, configured to oscillate and generate an output clock based on a level of a drain voltage dropped from a power supply voltage according to a current supplied by the reference clock; and
a current supply unit configured to supply a predetermined current through a node of the drain voltage before the predetermined interval returns after the inverter unit operates,
wherein the inverter unit includes a CMOS inverter connected between the drain voltage and ground.

12. The multiplying delay locked loop of claim 11,
further comprising a logic circuit configured to output a selection signal that causes the reference clock to be applied to the oscillator in response to the output clock output by the oscillator.

13. The multiplying delay locked loop of claim 11,
further comprising at least one digitally controlled delay line configured to adjust an arrival timing of the reference clock and the output clock fed back by the oscillator to the phase detector.

14. The multiplying delay locked loop of claim 11,
further comprising a frequency divider configured to divide the output clock generated by the oscillator by a predetermined division ratio and feed it back to the phase detector.
